(19) United States
(12) Patent Application Publication
(10) Pub. No.: US 2001/0047759 A1
(43) Pub. Date: Dec. 6, 2001

(54) Plasma CVD apparatus

(76) Inventors: Takayuki Matsui, Tokyo (JP); Koichi Ohto, Tokyo (JP); Tatsuya Usami, Tokyo (JP); Yoshiaki Tsuchiya, Tokyo (JP); Shigeo Ishikawa, Tokyo (JP)

Correspondence Address: ROSENMAN & COLIN LLP, 575 MADISON AVENUE, NEW YORK, NY, 10022-2585, US

(21) Appl. No.: 09/792,094

(22) Filed: Feb. 22, 2001

(30) Foreign Application Priority Data
Feb. 25, 2000 (JP) 50247/2000

(51) Int. Cl. C23C 16/00

(52) U.S. Cl. 118/723 E

(57) ABSTRACT

To provide a plasma CVD apparatus for forming a silicon nitride film and a fluorine-containing silicon oxide film in one and the same chamber, in which a NH₃ gas pipeline for introducing NH₃ gas as a part of raw material gases of the silicon nitride film and a SiF₄ gas pipeline for introducing SiF₄ gas as a part of the raw material gases of the fluorine-containing silicon oxide film are separately connected to an upper electrode also functioning as a shower head.

### BACKGROUND OF THE INVENTION

1. Field of the Invention

The present invention relates to a plasma CVD apparatus, and especially relates to a CVD apparatus for continuously forming a silicon nitride film (SiN film) and a fluorine-containing silicon oxide film (SiOF film) in one and the same chamber.

2. Description of the Prior Art

Following the tendency of making a semiconductor device ultra fine, fine multilayered wiring is inevitably required for a semiconductor device. In order to prevent operation speed retardation of the semiconductor device, it is desirable to use Cu wiring for the wiring, and it is necessary to use a film with a low dielectric constant for an interlayer insulating film.

The film with a low dielectric constant is supposed to be made available in relatively near future by using a SiOF film possible to be easily integrated in the same production process as a conventionally employed silicon oxide film (SiO₂ film).

A method for forming a SiO₂ film after formation of a SiN film is commonly employed for forming the interlayer insulating film on the conventional Cu wiring in order to prevent oxidation of the Cu wiring, and it is desirable to carry out these processes to successively form the SiN film and the SiO₂ film in one and the same chamber in order to reduce the cost. In the case of changing the SiO₂ film to a SiOF film to lower the dielectric constant, it is also desirable to successively carry out film formation processes in one and the same chamber in the same manner.

Next, referring to FIG. 5, a conventional example that a SiN film and a SiOF film are practically formed in one and the same chamber will be described.

With reference to cross-sectional view in FIG. 5, this example shows a parallel plate type plasma CVD apparatus. With regard to the configuration of the apparatus, there exist a chamber 11, a N₂ gas pipeline 1 equipped with a final valve 12, and a SiF₄ gas pipeline 2, a NH₃ gas pipeline 3, and a SiH₄ gas pipeline 4 joined to a single line and then equipped with a final valve 23, and these pipelines are connected to a chamber 11. An upper electrode 7 which also functions as a shower head and a high frequency power source 5 are installed in the upper part of the chamber 11 and a lower electrode 9 which functions as a heater and which is connected with a low frequency power source 6 is installed in the lower part of the chamber. A wafer 8 is mounted on the lower electrode 9. An exhaust part 10 is formed in a sidewall of the chamber.

Next, the steps for film formation will be described. At first, in a first step, a NH₃ gas valve 15, a SiH₄ gas valve 16 and the final valve 23 were opened, and NH₃ gas and SiH₄ gas were introduced into the chamber 11 to form a SiN film. The substrate temperature and the pressure in the chamber were controlled to be 400° C. and 4 to 5 Torr, respectively. About each 500 W power of the high frequency power source 5 and the low frequency power source 6 was applied to form a SiN film with about 100 nm thickness on the wafer 8 in this step.

Next, in a second step, after the film formation of the SiN film, the high frequency power source 5 and the low frequency power source 6 were turned off and the NH₃ gas valve 15 and the SiH₄ gas valve 16 were closed to stop introduction of NH₃ gas and SiH₄ gas and then the gases remaining in the pipelines from a SiF₄ gas valve 13A, the NH₃ gas valve 15, and the SiH₄ gas valve 16 to the chamber 11 were evacuated.

Then, the N₂ gas valve, which is the final valve 12, the SiF₄ gas valve 13A, the SiH₄ gas valve 16, and the final valve 23 were opened to introduce N₂ gas, SiF₄ gas and SiH₄ gas into the chamber 11 to try to form a SiOF film. The substrate temperature and the pressure in the chamber were controlled to be 400° C. and 4 to 5 Torr, respectively.

Though a SiOF film was expected to be formed on the wafer 8 in this step by applying each 500 W power of the high frequency power source 5 and the low frequency power source 6 to those electrodes, only particles of reaction products were found adhering to the wafer. Additionally, the pipelines were clogged in this step and gas flow was inhibited. According to the analysis of the disassembled pipeline near the final valve 23, a reaction product supposed to be [(NH₄) ₂SiF₆] was observed. Consequently, it was confirmed that reaction of SiF₄ and NH₃ was caused at a normal temperature in vacuum.

Next, since reaction of SiF₄ and NH₃ is caused at a normal temperature, continuous film formation in one and the same chamber is given up and hence, a method for respectively forming a SiN film and a SiOF film in independent chambers will be described with reference to FIG. 6 and FIG. 7.

FIG. 6 shows a chamber 11 for formation of a SiN film. NH₃ gas and SiH₄ gas were introduced into the chamber 11 by opening a final valve 14 to form a SiN film. The substrate temperature and the pressure in the chamber were controlled to be 400° C. and 4 to 5 Torr, respectively.

Respective gases were introduced into the chamber 11 through a NH₃ gas pipeline 3 and a SiH₄ gas pipeline 4. About each 500 W power of the high frequency power source 5 and the low frequency power source 6 was applied to form a SiN film with about 100 nm thickness on the wafer 8 in this step.

Further, after evacuation, the pressure in the chamber was increased to atmospheric pressure by N₂ gas and after being transferred to another chamber, the resultant wafer 8 was transferred to the chamber 11 for formation of SiOF film shown in FIG. 7.

FIG. 7 shows the chamber 11 for formation of SiOF film. By opening the final valves 12, 14B, N₂O gas and SiF₄ gas were introduced into the chamber 11 to form a SiOF film. The substrate temperature and the pressure in the chamber were controlled to be 400° C. and 4 to 5 Torr, respectively. About each 500 W power of the high frequency power source 5 and the low frequency power source 6 was applied to form a SiOF film on the wafer 8 in this step.

In this method, there were problems that since two chambers were employed, throughput was delayed in consideration of the time for the transportation between the chambers, and that the apparatus became expensive due to use of two chambers.

Regarding the conventional gas pipelines shown in FIG. 5, there existed problems as follows: the apparatus was so composed as to introduce NH₃ gas and SiF₄ gas through a single gas pipeline into the chamber and only a common final valve was installed, so that NH₃ gas evacuation is made incomplete and NH₃ gas and SiF₄ gas were mixed with each other in the gas pipeline before the chamber and consequently, reaction took place at a normal temperature and a reaction product [(NH₄)₂SiF₆) of NH₃ and SiF₄ was produced in the gas pipeline to clog the pipeline or to increase the quantity of particles on a wafer by the reaction product in the pipeline.

On the other hand, in the method for forming the SiN film and the SiOF film in separate chambers as shown in FIG. 6 and FIG. 7, there existed problems that the throughput was delayed and the cost of the apparatus was increased.

### BRIEF SUMMARY OF THE INVENTION

Object of the Invention

An object of the present invention is to provide a plasma CVD apparatus capable of preventing clogging of pipelines and forming a SiN film and a SiOF film in one and the same chamber.

Summary of the Invention

A plasma CVD apparatus for forming a silicon nitride film and a fluorine-containing silicon oxide film in a same single chamber according to the present invention comprises a NH₃ gas pipeline for introducing NH₃ gas as a part of raw material gases of the silicon nitride film and a SiF₄ gas pipeline for introducing SiF₄ gas as a part of raw material gases of the fluorine-containing silicon oxide film, in which these pipelines are separately connected to an upper electrode which also functions as a shower head.

### BRIEF DESCRIPTION OF THE DRAWINGS

The above-mentioned and other objects, features and a advantages of this invention will become more apparent by reference to the following detailed description of the invention taken in conjunction with the accompanying drawings, wherein:

FIG. 1 is a cross-section figure of a CVD apparatus showing a first embodiment of the present invention;

FIG. 2 is a cross-section figure of a CVD apparatus showing a second embodiment of the present invention;

FIG. 3 is a cross-section figure of a CVD apparatus showing a third embodiment of the present invention;

FIG. 4 is across-section figure of a CVD apparatus showing a fourth embodiment of the present invention;

FIG. 5 is a cross-section figure of a conventional CVD apparatus;

FIG. 6 is a cross-section figure of another conventional CVD apparatus; and

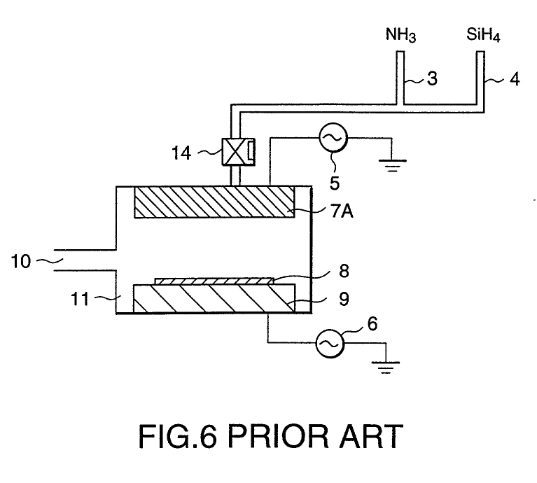

FIG. 7 is across-section figure of the other conventional CVD apparatus.

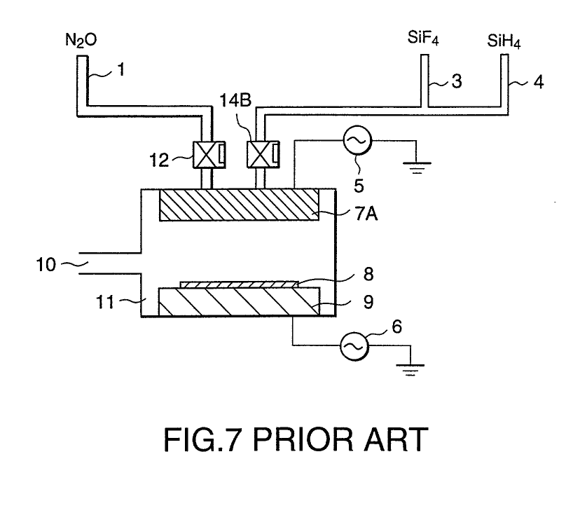

### DETAILED DESCRIPTION OF THE PREFERRED EMBODIMENTS

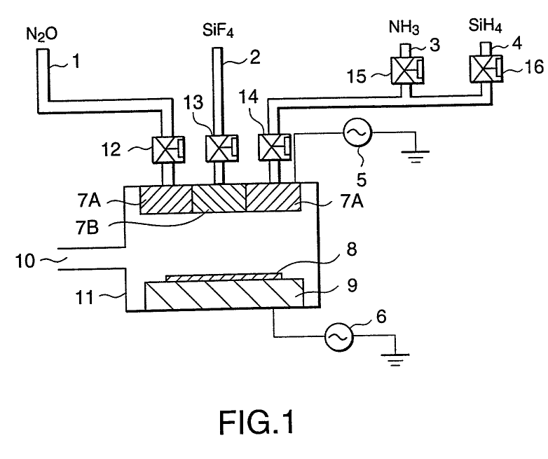

Embodiments of the present invention will be described in detail with reference to the drawings. FIG. 1 is a cross-section figure of a parallel plate type plasma CVD apparatus for illustrating a first embodiment of the present invention.

By reference to FIG. 1, in the parallel plate type plasma CVD apparatus of the present invention, a N₂ gas pipeline 1 equipped with a final valve 12 is connected with the outer circumferential part 7A of an upper electrode functioning also as a shower head. A NH₃ gas pipeline 3 and a SiH₄ gas pipeline 4 are joined to a single pipeline and also connected via a final valve 14 to the outer circumferential part 7A of the upper electrode functioning also as the shower head. Further a SiF₄ gas pipeline 2 equipped with a final valve 13 is connected to the center part 7B of the upper electrode functioning also as the shower head. The outer circumferential part and the center part 7A, 7B of the upper electrode functioning also as the shower head and a high frequency power source 5 are installed in the upper part of the chamber 11 and a lower electrode 9 also functioning as a heater to mount a wafer 8 thereon and a low frequency power source 6 are installed in the lower part of the chamber and an exhaust part 10 is formed in a side wall of the chamber.

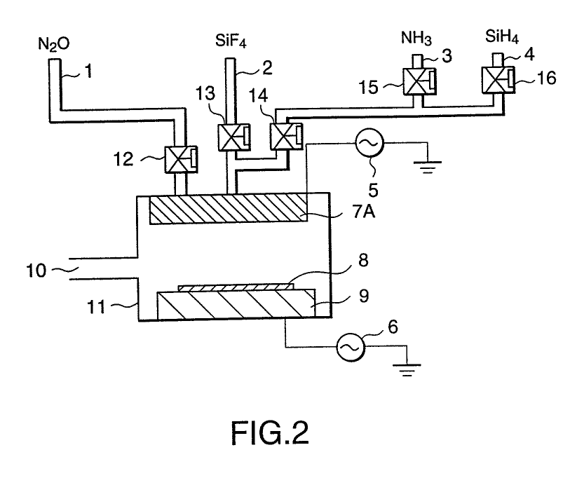

FIG. 2 is a cross-section figure of a parallel plate type plasma CVD apparatus for illustrating a second embodiment of the present invention and the parallel plate type plasma CVD apparatus has a configuration wherein: a N₂O gas pipeline 1 equipped with a final valve 12 is connected with an upper electrode 7 functioning also as a shower head; a NH₃ gas pipeline 3 equipped with a valve 15 and a SiH₄ gas pipeline 4 equipped with a valve 16 are joined to a single pipeline and via a final valve 14, joined in the downstream side to a SiF₄ gas pipeline 2 equipped with a valve 13 and further connected to the upper electrode 7 functioning also as the shower head; and the upper electrode 7 functioning also as the shower head and a high frequency power source 5 are installed in the upper part of the chamber 11 and a lower electrode 9 also functioning as a heater to mount a wafer 8 thereon and a low frequency power source 6 are installed in the lower part of the chamber and an exhaust part 10 is formed in a side wall of the chamber.

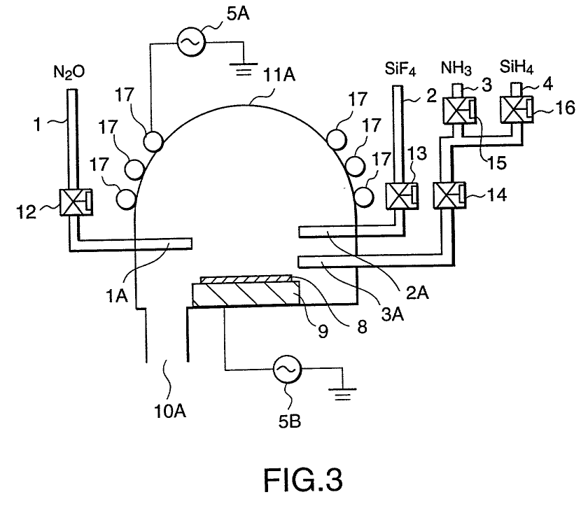

FIG. 3 is a cross-section figure of a high density plasma CVD apparatus for illustrating a third embodiment of the present invention and the high density plasma CVD apparatus has a configuration wherein: a N₂O gas pipeline 1 equipped with a final valve 12 and a SiF₄ gas pipeline 2 equipped with a final valve 13 are connected with a chamber 11A and a NH₃ gas pipeline 3 and a SiH₄ gas pipeline 4 are joined to a single pipeline and via a final valve 14 further connected to the chamber 11A as to introduce respective gases into the chamber through gas nozzles 1A, 2A, and 3A; and a coil 17 and a high frequency power source 5A are installed in a dome part of the upper part of the chamber 11A, a lower electrode 9 also functioning as a heater to mount a wafer 8 thereon and a high frequency power source 5B are installed in the lower part of the chamber, and an exhaust part 10A is formed in a side wall of the chamber.

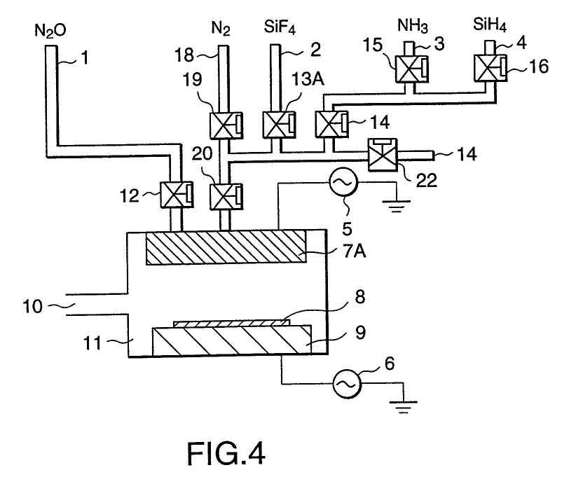

FIG. 4 is a parallel plate type plasma CVD apparatus for illustrating a fourth embodiment of the present invention and the parallel plate type plasma CVD apparatus has a configuration wherein: a N₂O gas pipeline 1 equipped with a final valve 12 is connected with an upper electrode 7 functioning also as a shower head; a NH₃ gas pipeline 3 equipped with a NH₃ gas valve 15 and a SiH₄ gas pipeline 4 equipped with a SiH₄ gas valve 16 are joined to a single pipeline which is further equipped with a NH₃/SiH₄ valve 14A in the downstream side; the single pipeline, N₂ gas pipeline 18 equipped with a N₂ gas valve 19, and a SiF₄ gas pipeline 2 equipped with a SiF₄ gas valve 13A are joined to a single line extending in two directions, which is connected to a gas exhaust part 21 via an exhaust valve 22 in one direction and to an upper electrode 7 functioning also as the shower head via a final valve 20 in the other direction; and the upper electrode 7 functioning also as the shower head and a high frequency power source 5 are installed in the upper part of the chamber 11, a lower electrode 9 also functioning as a heater to mount a wafer 8 thereon and a low frequency power source 6 are installed in the lower part of the chamber, and an exhaust part 10 is formed in a side wall of the chamber. Additionally, a N₂ gas pipeline 18 may be installed based on the necessity.

The CVD film formation will be described below based on respective embodiments of the present invention.

At first, the CVD film formation will be described with reference to the CVD apparatus of the first embodiment shown in FIG. 1. At first, in a first step, a NH₃ gas valve 15, a SiH₄ gas valve 16 and the final valve 14 were opened and NH₃ gas and SiH₄ gas were introduced into the chamber 11 through the outer circumferential part 7A of the upper electrode also functioning as a shower head to form a SiN film. The film formation temperature and the pressure in the chamber were controlled to be 400° C. and 4 to 5 Torr, respectively. About each 500 W power of the high frequency power source 5 and the low frequency power source 6 was applied to form a SiN film with about 100 nm thickness on the wafer 8 in this step.

Secondarily, in a second step, after the film formation of the SiN film, the high frequency power source 5 and the low frequency power source 6 were turned off and then the gases remaining in the pipelines from the NH₃ gas valve 15 and the SiH₄ gas valve 16 to the chamber 11 were evacuated.

Thirdly, in a third step, the final valve 12 was opened to introduce N₂ gas into the chamber 11 through the outer circumferential part 7A of the upper electrode also functioning as the shower head and the final valve 13 was opened to introduce SiF₄ into the chamber 11 through the center part 7B of the upper electrode also functioning as the shower head. Further, the SiH₄ gas valve 16 and the final valve 14 were opened to introduce SiH₄ gas into the chamber 11 to form a SiOF film. The substrate temperature and the pressure in the chamber were controlled to be 400° C. and 4 to 5 Torr, respectively. About each 500 W power of the high frequency power source 5 and the low frequency power source 6 was applied to form a SiOF film with about 800 nm thickness on the wafer 8 in this step.

Next, in a fourth step, after the film formation of the SiOF film, the high frequency power source 5 and the low frequency power source 6 were turned off and the final valves 12, 13 were closed to stop introduction of N₂O gas and SiF₄ gas, the SiH₄ gas valve 16 was closed to stop introduction of SiH₄ gas and then the gases remaining in the pipelines from the final valves 12, 13, the NH₃ gas valve 15, and the SiH₄ gas valve 16 to the chamber 11 were evacuated. Hereafter, it was succeeded by the next film formation step.

In the case of employing this CVD apparatus, since the SiF₄ gas line and the NH₃ gas line were separated, SiF₄ gas and NH₃ gas were inhibited to be mixed with each other in any step in the pipelines and therefore a SiN film and SiOF film were made possible to be successively formed without causing clogging of the pipelines with a production product.

Next, the CVD film formation will be described with reference to the CVD apparatus of the second embodiment shown in FIG. 2. At first, in a first step, a NH₃ gas valve 15, a SiH₄ gas valve 16 and the final valve 14 were opened and NH₃ gas and SiH₄ gas were introduced into the chamber 11 through the upper electrode 7 also functioning as a shower head to form a SiN film. At that time, the final valve 13 interlockingly operated with the NH₃ gas valve 15 was closed. The film formation temperature and the pressure in the chamber were controlled to be 400° C. and 4 to 5 Torr, respectively. About each 500 W power of the high frequency power source 5 and the low frequency power source 6 was applied to form a SiN film with about 100 nm thickness on the wafer 8 in this step.

Secondarily, in a second step, after the film formation of the SiN film, the high frequency power source 5 and the low frequency power source 6 were turned off, the NH₃ gas valve 15 and the SiH₄ gas valve 16 were closed to stop introduction of NH₃ gas and SiH₄ gas, and the gases remaining in the pipelines from the final valves 12 and 13, the NH₃ gas valve 15 and the SiH₄ gas valve 16 to the chamber 11 were evacuated.

Thirdly, in a third step, the final valve 14 was closed and gases remaining in the pipelines from the final valves 12, 13, 14 to the chamber 11 were evacuated.

Next, in a fourth step, the final valve 12 was opened to introduce N₂O gas into the chamber 11 through the outer circumferential part 7A of the upper electrode also functioning as the shower head and the final valve 13 was opened and further the SiH₄ gas valve 16 and the final valve 14 were opened to introduce SiF₄ and SiH₄ gas respectively into the chamber 11 through the upper electrode 7 also functioning as the shower head to form a SiOF film. At this time, the NH₃ gas valve 15 interlockingly operated with the final valve 13 was closed. The film formation temperature and the pressure in the chamber were controlled to be 400° C. and 4 to 5 Torr, respectively. About each 500 W power of the high frequency power source 5 and the low frequency power source 6 was applied to form a SiOF film with about 800 nm thickness on the wafer 8 in this step.

Next, in a fifth step, after the film formation of the SiOF film, the high frequency power source 5 and the low frequency power source 6 were turned off and the final valves 12 and 13 were closed to stop introduction of N₂O gas and SiF₄ gas, the SiH₄ gas valve 16 was closed to stop introduction of SiH₄ gas and then the gases remaining in the pipelines from the final valves 12 and 13, the NH₃ gas valve 15, and the SiH₄ gas valve 16 to the chamber 11 were evacuated.

Finally, in a sixth step, the final valve 14 was closed and gases remaining in pipelines from the final valves 12, 13 and 14 to the chamber 11 were evacuated.

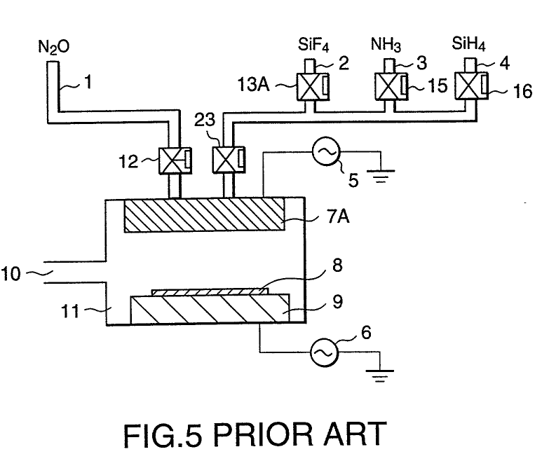

In the case of employing this CVD apparatus, since SiF₄ gas and NH₃ gas were kept from each other in pipelines in any step and therefore successive film formation was made possible without causing clogging of the pipelines. Further, the configuration of this apparatus, being compared with that of the first embodiment, was so constituted as to utilize the upper electrode 7 also functioning as the shower head in common for respective gases to introduce the gases into the chamber 11 and the apparatus had an advantage that the apparatus could be obtained at a low cost only by reconstructing a conventional CVD apparatus shown in FIG. 5 by replacing only pipelines.

Next, the CVD film formation will be described with reference to the CVD apparatus of the third embodiment shown in FIG. 3. At first, in a first step, a NH₃ gas valve 15, a SiH₄ gas valve 16 and the final valve 14 were opened and NH₃ gas and SiH₄ gas were introduced through a NH₃ and SiH₄ gas nozzle 3A into the chamber 11A to form a SiN film. The film formation temperature and the pressure in the chamber were controlled to be 400° C. and 4 to 5 Torr, respectively. About 1,000 to 4,000 W power and about 3,000 to 4,000 W power of the high frequency power sources 5A and 5B, receptively, were applied to form a SiN film with about 100 nm thickness on the wafer 8 in this step.

Secondarily, in a second step, after the film formation of the SiN film, the high frequency power sources 5A, 5B were turned off and then the NH₃ gas valve 15 and the SiH₄ gas valve 16 were closed to stop introduction of NH₃ gas and SiH₄ gas and the gases remaining in the pipelines from the final valves 12, 13, the NH₃ gas valve 15 and the SiH₄ gas valve 16 to the chamber 11 were evacuated.

Thirdly, in a third step, the final valves 12, 13 and the SiH₄ gas valve 16 were opened to introduce N₂O gas, SiF₄ gas and SiH₄ gas into the chamber 11 through a N₂O gas nozzle 1A, a SiF₄ gas nozzle 2A, and a NH₃ and SiH₄ gas nozzle 3A, respectively, to form a SiOF film. The film formation temperature and the pressure in the chamber were controlled to be 400° C. and 4 to 5 Torr, respectively. About 1,000 to 4,000 W power and about 3,000 to 4,000 W power of the high frequency power sources 5A, 5B were applied to form a SiOF film with about 800 nm thickness on the wafer 8 in this step.

Next, in a fourth step, after the film formation of the SiOF film, the high frequency power sources 5A, 5B were turned off and the final valves 12, 13 and the SiH₄ gas valve 16 were closed to stop introduction of N₂O gas, SiF₄ gas, and SiH₄ gas and then the gases remaining in the pipelines from the final valves 12, 13 and the SiH₄ gas valve 16 to the chamber 11 were evacuated.

In the case of employing this CVD apparatus, since SiF₄ gas and NH₃ gas were kept from each other in pipelines in any step and therefore successive film formation was made possible without causing clogging of the pipelines. Further, compared with that of the first and the second embodiments, the apparatus had an advantage that the apparatus is capable of forming high quality films owing to utilization of high density plasma.

Next, the CVD film formation will be described with reference to the CVD apparatus of the fourth embodiment shown in FIG. 4. At first, in the first step, a NH₃ gas valve 15, a SiH₄ gas valve 16, a NH₃—SiH₄ gas valve 14A, and the final valve 20 were opened and NH₃ gas and SiH₄ gas were introduced into the chamber 11 through the upper electrode also functioning as a shower head to form a SiN film. At that time, the SiF₄ gas valve 13A interlockingly operated with the NH₃ gas valve 15 was closed. The film formation temperature and the pressure in the chamber were controlled to be 400° C. and 4 to 5 Torr, respectively. About each 500 W power of the high frequency power source 5 and the low frequency power source 6 was applied to form a SiN film with about 100 nm thickness on the wafer 8 in this step.

Secondarily, in a second step, after the film formation of the SiN film, the high frequency power source 5 and the low frequency power source 6 were turned off and then the NH₃ gas valve 15 and the SiH₄ gas valve 16 were closed to stop introduction of NH₃ gas and SiH₄ gas and the gases remaining in the pipelines from the N₂ gas valve 19, the SiH₄ gas valve 13A, the NH₃ gas valve 15, the SiH₄ gas valve 16, and the exhaust valve 22 to the chamber 11 were evacuated.

Thirdly, in a third step, the NH₃—SiH₄ gas valve 14A was closed and the N₂ gas valve 19 was opened to fill N₂ gas in pipelines from the SiF₄ gas valve 13A and the NH₃—SiH₄ valve 14A to the exhaust valve 22 and the final valve 20.

Next, in a fourth step, the exhaust valve 22 was opened to evacuate the pipelines to vacuum from the N₂ gas valve 19, the SiF₄ gas valve 13A and the NH₃—SiH₄ valve 14A to the final valve 20.

Next, in a fifth step, the N₂O gas valve 12 was opened to introduce N₂O gas into the chamber 11 through the upper electrode 7 also functioning as the shower head and the exhaust valve 22 was closed and further the SiF₄ gas valve 13A and the NH₃—SiH₄ valve 14A, the SiH₄ gas valve 16, and the final valve 20 were opened to introduce SiF₄ and SiH₄ gas respectively into the chamber 11 through the upper electrode 7 also functioning as the shower head to form a SiOF film. At that time, the NH₃ gas valve 15 interlockingly operated with the SiF₄ gas valve 13A was closed. The substrate temperature and the pressure in the chamber were controlled to be 400° C. and 4 to 5 Torr, respectively. About each 500 W power of the high frequency power source 5 and the low frequency power source 6 was applied to form a SiOF film with about 800 nm thickness on the wafer 8 in this step.

Next, in a sixth step, after the film formation of the SiOF film, the high frequency power source 5 and the low frequency power source 6 were turned off and the N₂O gas valve 12 was closed to stop introduction of N₂O gas and the SiF₄ gas valve 13A and the SiH₄ gas valve 16 were closed to stop introduction of SiF₄ gas and SiH₄ gas and then the gases remaining in the pipelines from the N₂ gas valve 19, the SiF₄ gas valve 13A, the NH₃ gas valve 15, the SiH₄ gas valve 16 and the exhaust valve 22 to the chamber 11 were evacuated.

Next, in a seventh step, the NH₃—SiH₄ gas valve 14A was closed and the N₂ gas valve 19 was opened to fill N₂ gas in pipelines from the SiF₄ gas valve 13A, the NH₃—SiH₄ gas valve 14A, and the exhaust valve 22 to the final valve 20.

Finally, in an eighth step, as same in the fourth step, the exhaust valve 22 was opened to evacuate the pipelines to vacuum from the N₂ gas valve 19, the SiF₄ gas valve 13A and the NH₃—SiH₄ valve 14A to the final valve 20.

In the case of employing this CVD apparatus, since the pipelines were evacuated to vacuum after film formation of the SiN film or the SiOF film, and then N₂ gas was enclosed, and the pipelines were evacuated to vacuum, as compared with the second embodiment, the remaining gases could be evacuated at a high efficiency. As a result, SiF₄ and NH₃ were kept from each other in pipelines in any step and therefore successive film formation was made possible without causing clogging of the pipelines.

Although in the method for forming a film utilizing the fourth embodiment, the evacuation and N₂ pressurization are repeatedly carried out between the final valve 20 and the exhaust valve 22, the N₂ filling may be omitted by sufficiently carrying out the evacuation.

Incidentally, although the foregoing embodiments have been described with reference to the cases of applying the present invention to the parallel plate type plasma CVD apparatus and the high density plasma CVD apparatus, needless to say, the present invention may be applied to a remote plasma CVD apparatus having a configuration in which plasma generated in another site is introduced into the chamber.

As described above, a plasma CVD apparatus of the present invention for successive formation of a SiN film and SiOF film in one and the same chamber is effective to prevent reaction of SiF₄ gas and NH₃ gas in pipelines in a normal temperature since the NH₃ gas and SiF₄ gas are introduced into the chamber through separate gas lines or through gas lines equipped with separate valves independently interlockingly operated with the NH₃ gas pipeline and the SiF₄ gas pipeline and is, therefore, effective to prevent production of a reaction product [(NH₄) ₂SiF₆] of NH₃ and SiF₄, and avoid clogging of the pipelines and production of reaction products in the pipelines. Further, since the SiN film and the SiOF film can successively be formed in one and the same chamber, the production cost can be lowered and the throughput can be heightened.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A plasma CVD apparatus for forming a silicon nitride film and a fluorine-containing silicon oxide film in one and the same chamber, wherein a NH₃ gas pipeline for introducing NH₃ gas as a part of raw material gases of said silicon nitride film and a SiF₄ gas pipeline for introducing SiF₄ gas as a part of said raw material gases of the fluorine-containing silicon oxide film are separately connected to an upper electrode also functioning as a shower head.

2. The plasma CVD apparatus according to claim 1, wherein said upper electrode also functioning as a shower head is composed of a center part to which said SiF₄ gas pipeline for introducing SiF₄ gas is connected and a peripheral part to which pipelines for other gases are connected.

3. A plasma CVD apparatus for forming a silicon nitride film and a fluorine-containing silicon oxide film in one and the same chamber, wherein a NH₃ gas pipeline for introducing NH₃ gas as a part of raw material gases of said silicon nitride film and a SiF₄ gas pipeline for introducing SiF₄ gas as a part of said raw material gases of said fluorine-containing silicon oxide film are separately equipped with their respective valves before these pipelines are joined together and the valve installed in said SiF₄ gas pipeline and the valve installed in said NH₃ gas pipeline are made interlockingly operable in such a manner that when one of the valves is opened, the other valve is closed.

4. The plasma CVD apparatus according to claim 3, wherein said plasma CVD apparatus comprises a valve between the valves installed in said SiF₄ gas pipeline and in said NH₃ gas pipeline and said chamber, and a mechanism capable of evacuation independently in said gas pipeline between these valves.

5. The plasma CVD apparatus according to claim 3, wherein said plasma CVD apparatus comprises a valve between the valves installed in said SiF₄ gas pipeline and in said NH₃ gas pipeline and said chamber, and a mechanism capable of repeatedly carrying out evacuation and N₂ pressurization independently in said gas pipeline between these valves.

6. The plasma CVD apparatus according to claim or 3, wherein said plasma CVD apparatus is a parallel plate type plasma CVD apparatus, a high density plasma CVD apparatus, or a remote plasma CVD apparatus.
